(19) United States
(12) Patent Application Publication
(10) Pub. No.: US 2025/0159803 A1
(43) Pub. Date: May 15, 2025

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventor: Youngwoong Cho, Suwon-si (KR)

(73) Assignee: SAMSUNG ELECTRO-MECHANICS CO., LTD., Suwon-si (KR)

(21) Appl. No.: 18/680,560

(22) Filed: May 31, 2024

(30) Foreign Application Priority Data
Nov. 13, 2023 (KR) 10-2023-0156719

(51) Int. Cl. H05K 1/11; H05K 1/03

(52) U.S. Cl. CPC H05K 1/111; H05K 1/0366; H05K 2201/09036; H05K 2201/2081

(57) ABSTRACT

A disclosed circuit board includes: an insulating layer that has a first surface and a second surface facing each other and includes a trench portion concavely recessed from the first surface of the insulating layer; a first connection pad that is embedded within the insulating layer and is exposed from the first surface of the insulating layer; and a first protective layer that covers the insulating layer and is opened to expose the first connection pad and the trench portion from the first surface of the insulating layer.

### CROSS-REFERENCE TO RELATED APPLICATION

This application claims priority to and the benefit of Korean Patent Application No. 10-2023-0156719 filed at the Korean Intellectual Property Office on Nov. 13, 2023, the entire contents of which are incorporated herein by reference.

### TECHNICAL FIELD

The present disclosure relates to a circuit board and a method of fabricating the circuit board.

### BACKGROUND

An electronic product tends to become increasingly down-sized and multifunctional, so that a packaging technology is also advancing. Particularly, a package-on-package (POP) structure plays an important role in improving performance and function of the electronic product. The POP structure integrates various functions, enables down-sizing, and includes a multi-layered package to perform connection between an upper package and a lower package. The connection is often made using a solder ball, and the solder ball provides electrical and mechanical connections between the packages and simultaneously maintains conductivity of each package.

However, a certain problem arises if an interposer substrate and a memory substrate are mounted up and down in the POP structure and the connection using the solder ball is performed. If an underfill component is injected after the lower package is connected to the upper package with the solder ball, a phenomenon where the underfill component bleeds to a connection portion using the solder ball is discovered. Because the bleeding phenomenon deteriorates reliability between the packages and affects performance of the electronic product, a need for an improved packaging technology to solve the problem is emerging.

### SUMMARY

One aspect of a disclosed embodiment is to provide a circuit board that secures packaging assemblability by improving a board structure to protect a connection portion using a solder ball that provides a connection between packages in a packaging process from bleeding of an underfill material, and a method of fabricating the circuit board.

However, problems to be solved by embodiments of the present disclosure are not limited to the above-described problem and may be variously extended in a range of technical ideas included in the present disclosure.

A circuit board according to an embodiment includes: an insulating layer that has a first surface and a second surface facing each other and includes a trench portion concavely recessed from the first surface of the insulating layer; a first connection pad that is embedded within the insulating layer and is exposed from the first surface of the insulating layer; and a first protective layer that covers the insulating layer and is opened to expose the first connection pad and the trench portion from the first surface of the insulating layer.

The first protective layer may include a first opening exposing the first connection pad and a second opening exposing the trench portion.

In terms of a width along a first direction parallel to the first surface of the insulating layer, a width of the second opening may be greater than a width of the trench section.

In terms of a width along a first direction parallel to the first surface of the insulating layer, a width of the first opening may be less than a width of the first connection pad.

A bottom surface of the trench portion may be disposed to be further retreated than an exposed surface of the first connection pad.

The bottom surface of the trench portion may be disposed to be further retreated than a bottom surface of the first connection pad.

A recessed depth of the trench portion may be greater than a thickness of the first connection pad along a second direction perpendicular to the first surface of the insulating layer.

A recessed depth of the trench portion may be less than a thickness of the insulating layer along a second direction perpendicular to the first surface of the insulating layer.

The trench portion may be disposed adjacent to the first connection pad.

The circuit board may further include a plurality of first connection pads including the first connection pad, in which the trench portion may be disposed between first connection pads that are adjacent to each other among the plurality of first connection pads.

An exposed surface of the first connection pad may be disposed on the same surface as the first surface of the insulating layer.

The circuit board may further include a second connection pad disposed to protrude from the second surface of the insulating layer.

The circuit board may further include a second protective layer that at least partially covers the insulating layer and the second connection pad on the second surface of the insulating layer.

The insulating layer may include a prepreg (PPG).

The protective layer may include a solder resist (SR).

A method of fabricating the circuit board according to an embodiment includes: forming a conductive layer including a first metal on a seed layer including a second metal; patterning a first plating resist covering the conductive layer and plating the first metal to form a protruding pattern layer on the conductive layer; patterning a second plating resist covering the conductive layer and the protruding pattern layer and plating the second metal to form a connection pad on the conductive layer; forming an insulating layer to cover the protruding pattern layer and the connection pad; and removing the protruding pattern layer by etching the protruding pattern layer and forming a trench portion concavely recessed on a surface of the insulating layer.

The method may further include forming a protective layer opened to expose the connection pad and the trench portion on the surface of the insulating layer.

The second metal may include copper (Cu) and the first metal may include tin (Sn).

The trench portion may be formed at a portion corresponding to the protruding pattern layer.

The circuit board according to the disclosed embodiment may secure packaging assemblability by improving a board structure (or a substrate structure) to protect a connection portion using a solder ball that provides a connection between packages in a packaging process from bleeding of an underfill material.

According to the circuit board according to the embodiment, a connection pad may be formed at a circuit board manufactured using an embedded trace substrate (ETS) method and a board structure with no step difference between an embedded copper pattern and a surface of a PPG insulating layer may be manufactured, so that packaging assembly yield is improved.

### BRIEF DESCRIPTION OF THE DRAWINGS

FIG. 1 is a cross-sectional view showing a circuit board according to an embodiment.

FIGS. 2 through 17 are process cross-sectional views showing a method of fabricating the circuit board shown in FIG. 1.

### DETAILED DESCRIPTION OF THE EMBODIMENTS

The present disclosure will be described more fully hereinafter with reference to the accompanying drawings, in which embodiments of the disclosure are shown. The drawings and description are to be regarded as illustrative in nature and not restrictive. Like reference numerals designate like elements throughout the specification. In the drawings, size and thickness of each element are arbitrarily illustrated for convenience of description, and the present disclosure is not necessarily limited to as illustrated in the drawings.

In addition, the attached drawing is only for easy understanding of the embodiment disclosed in the present specification, and the technical idea disclosed in this specification is not limited by the attached drawing, and all changes included in the spirit and technical range of the present disclosure, should be understood to include equivalents or substitutes.

Terms including an ordinal number such as first, second, and the like may be used to describe various configurations elements, but the constituent elements are not limited by the terms. The terms are used only for the purpose of distinguishing one constituent element from another.

It will be understood that when an element such as a layer, film, region, or substrate is referred to as being “on” or “above” another element, it may be directly on the other element or intervening elements may also be present. In contrast, when an element is referred to as being “directly on” another element, there are no intervening elements present. Further, throughout the specification, the word “on” or “above” a target element will be understood to be disposed above or below the target element, and will not necessarily be understood to be disposed “at an upper side” based on an opposite to gravity direction.

In the present application, terms such as “comprise” or “have” are intended to designate that a feature, number, step, operation, constituent element, part, or combination thereof described in the specification exists, and it should be understood as not precluding the possibility of the presence or addition of and one or more other features, numbers, steps, actions, constituent elements, parts, or combinations thereof. In addition, unless explicitly described to the contrary, the word “comprise” and variations such as “comprises” or “comprising” will be understood to imply the inclusion of stated elements but not the exclusion of any other elements.

Further, throughout the specification, the phrase “on a plane” means viewing a target portion from the top, and the phrase “on a cross-section” means viewing a cross-section formed by perpendicularly cutting a target portion from the side.

In addition, throughout the specification, “connected” does not mean only when two or more constituent elements are directly connected, but also when two or more constituent elements are indirectly connected through another constituent element, or when physically connected or electrically connected, and it may include a case in which substantially integral parts are connected to each other although they are referred to by different names according to positions or functions.

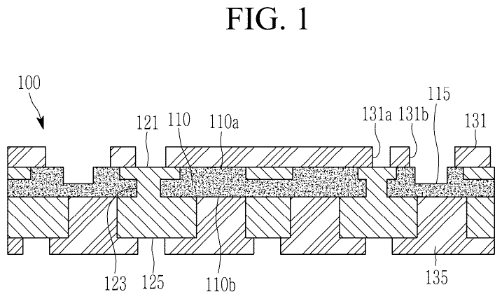

FIG. 1 is a cross-sectional view showing a circuit board according to an embodiment.

Referring to FIG. 1, the circuit board 100 according to the present embodiment includes an insulating layer 110, a circuit wiring embedded in the insulating layer 110, and protective layers 131 and 135 covering at least one surface of the insulating layer 110. The insulating layer 110 and the circuit wiring may have an embedded trace substrate (ETS) structure. The circuit board 100 may be a printed circuit board that may be used for a semiconductor package.

The insulating layer 110 may have a first surface 110a and a second surface 110b facing each other, and may include a resin insulating layer. The insulating layer 110 may be a thermosetting resin such as an epoxy resin, a thermoplastic resin such as polyimide, or a resin (for example, a prepreg) impregnated with a reinforcing material such as a glass fiber or an inorganic filler. Additionally, the insulating layer 110 may include a thermosetting resin and/or a photo-curing resin, but the present disclosure is not limited thereto.

The circuit wiring may be embedded within the insulating layer 110, and may include a first connection pad 121 exposed from the insulating layer 110 on the first surface 110a and a second connection pad 125 protruding from the second surface 110b of the insulating layer 110. The circuit wiring may include a via 123 that penetrates the insulating layer 110 within the insulating layer 110 to connect the first connection pad 121 and the second connection pad 125, and may include a wiring that extends without being exposed within the insulating layer 110. The circuit wiring may include copper (Cu), and may be connected to terminals of an external circuit component through the first connection pad 121 exposed from the insulating layer 110 and the second connection pad 125 protruding from the insulating layer 110.

In this case, an exposed surface of the first connection pad 121 may be disposed on the same surface as the first surface 110a, and may not form a step difference. That is, even if the insulating layer 110 has the ETS structure, the exposed surface of the first connection pad 121 embedded in the insulating layer 110 may not be recessed from the surface of the insulating layer 110.

The protective layers 131 and 135 may include the first protective layer 131 covering the first surface 110a of the insulating layer 110 and the second protective layer 135 covering the second surface 110b. The first protective layer 131 may be opened to expose the first connection pad 121 on the first surface 110a. The second protective layer 135 may cover the second connection pad 125 along with the insulating layer 110 at the second surface 110b, and may also be opened to expose a portion of the second connection pad 125. The protective layers 131 and 135 may include a solder resist layer.

The insulating layer 110 may include a trench portion 115 that is concavely recessed from the first surface 110a. The first protective layer 131 covering the insulating layer 110 may be opened to expose the trench portion 115. Therefore, the first protective layer 131 may include a first opening 131a that exposes the first connection pad 121 and a second opening 131b that exposes the trench portion 115. In terms of a width along a first direction parallel to the first surface 110a of the insulating layer 110, a width of the second opening 131b may be formed to be larger than a width of the trench portion 115. Additionally, in terms of the width along the first direction, a width of the first opening 131a may be formed to be smaller than a width of the first connection pad 121.

A bottom surface of the trench portion 115 may be disposed to be further retreated from the surface of the insulating layer 110 than the exposed surface of the first connection pad 121. In this case, a recessed depth of the trench portion 115 may be formed to be greater than a thickness of the first connection pad 121 along a second direction perpendicular to the first surface 110a of the insulating layer 110. Additionally, the recessed depth of the trench portion 115 may be formed to be smaller than a thickness of the insulating layer 110 along the second direction.

The first connection pad 121 may be provided in a plural number, and the trench portion 115 may be disposed adjacent to the first connection pad 121. Additionally, the trench portion 115 may be disposed between first connection pads 121 adjacent to each other.

In a packaging process, an electronic element (not shown) may be mounted on the circuit board 100 through a solder ball (not shown) disposed at the first connection pad 121. In this case, an underfill material may be injected between the electronic element and the circuit board 100. Underfill bleeding where the injected underfill material overflows from the first opening 131a of the first protective layer 131 exposing the first connection pad 121 to flow to a surrounding region may occur. The trench portion 115 adjacent to the first connection pad 121 may accommodate the overflowing underfill material so that the overflowing underfill material flowing into another surrounding first connection pad 121 can be avoided. Thus, the trench portion 115 adjacent to the first connection pad 121 may prevent contamination.

According to the embodiment shown in FIG. 1, one insulating layer 110, two connection pads 121 and 125, and the via 123 connecting the one insulating layer 110 and the two connection pads 121 and 125 are shown, but the present disclosure is not limited thereto. Further, a larger number of build-up insulating layers and a larger number of build-up circuit wiring layers may be included, and this also falls within the scope of the present disclosure.

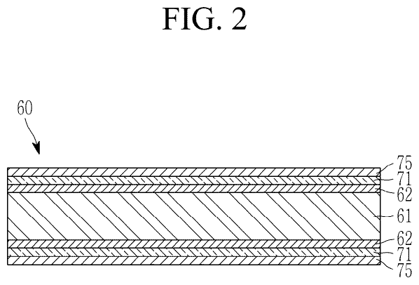

FIGS. 2 to 17 are process cross-sectional views showing a method of fabricating the circuit board shown in FIG. 1.

Referring to FIGS. 2 to 5, a carrier substrate 60 in which a first seed layer 71 and a conductive layer 75 are disposed on at least one surface thereof is prepared, and a protruding pattern layer 78 is formed on the conductive layer 75 through a protruding pattern formation process. The carrier substrate 60 may be a board in which a copper foil layer 62 is laminated on both surfaces of an insulating material 61, and the first seed layer 71 and the copper foil layer 62 may be separated from each other. The insulating material 61 may be a dual detach core (DCF) layer. The conductive layer 75 may be formed by plating on the first seed layer 71 (see FIG. 2). The conductive layer 75 may include a first metal, and the first seed layer 71 may include a second metal. The first metal may be a different metal from the second metal, and etching conditions of the first metal and the second metal may be different. For example, the first metal may include tin (Sn), and the second metal may include copper (Cu).

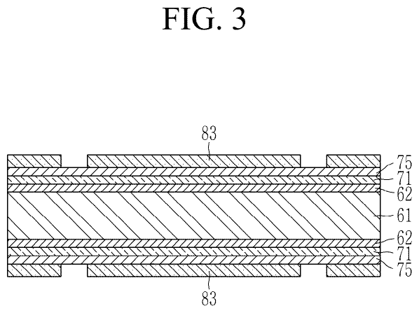

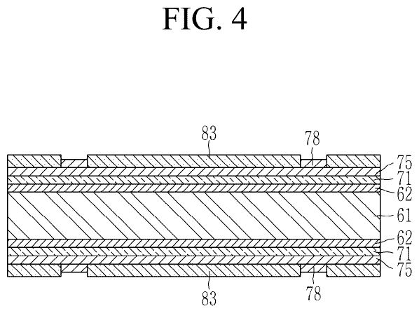

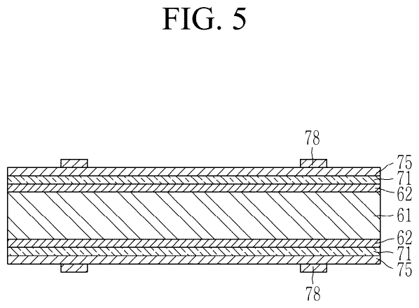

A first plating resist pattern 83 removed through exposure and development may be formed only at a portion where the protruding pattern layer 78 is to be formed on the carrier substrate 60 (see FIG. 3). The protruding pattern layer 78 may be formed to have a protruding portion where the first metal having conductivity is plated at a portion of the conductive layer 75 exposed through an opening of the first plating resist pattern 83 patterned (see FIG. 4). After the protruding pattern layer 78 is formed, the first plating resist pattern 83 is removed (see FIG. 5).

Although the present embodiment shows forming the protruding pattern layer 78 on both surfaces of the carrier substrate 60, it is also possible to form the protruding pattern layer 78 on only one surface of the carrier substrate 60, and this also falls within the scope of the present disclosure.

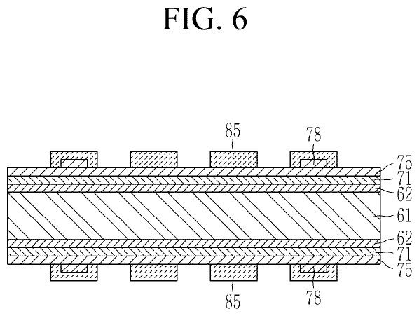

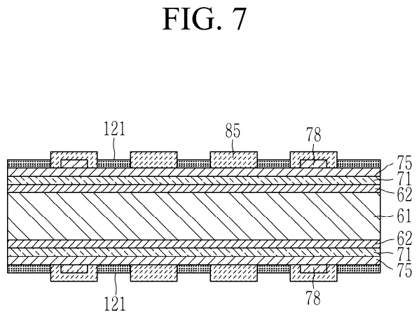

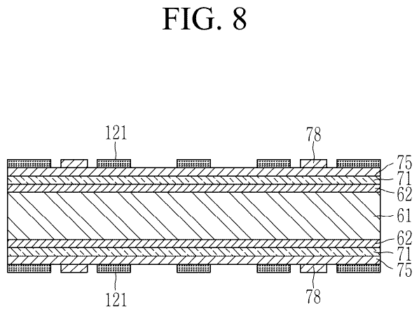

Referring to FIGS. 6 to 8, the first connection pad 121 is formed on the conductive layer 75 through a circuit formation process. A second plating resist pattern 85 removed through exposure and development may be formed only at a portion where the first connection pad 121 will be formed on the conductive layer 75 (see FIG. 6). The first connection pad 121 may be formed by plating the second metal having conductivity on a portion of the conductive layer 75 exposed through an opening of the second plating resist pattern 85 patterned (see FIG. 7). The portion of the conductive layer 75 and the protruding pattern layer 78 may be covered with the second plating resist pattern 85, and the second plating resist pattern 85 may be removed after formation of the first connection pad 121 (see FIG. 8).

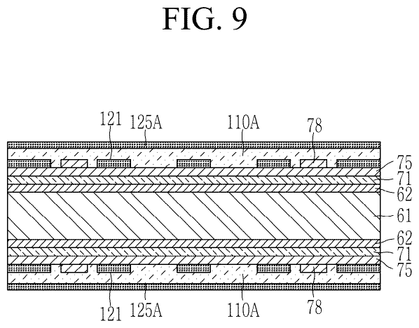

Referring to FIG. 9, an insulating layer 110A is laminated so that the first connection pad 121 is embedded, and a second seed layer 125A is formed on an upper surface of the insulating layer 110A. The second seed layer 125A may be formed to form the second connection pad 125, and may be used without restriction as long as it is a conductive metal, but copper (Cu) is commonly used as a material of the second seed layer 125A.

The insulating layer 110A may include a resin insulating layer. The insulating layer 110A may be a thermosetting resin such as an epoxy resin, a thermoplastic resin such as polyimide, or a resin (for example, a prepreg) impregnated with a reinforcing material such as a glass fiber or an inorganic filler. Additionally, the insulating layer 110A may include a thermosetting resin and/or a photo-curing resin, but the present disclosure is not limited thereto.

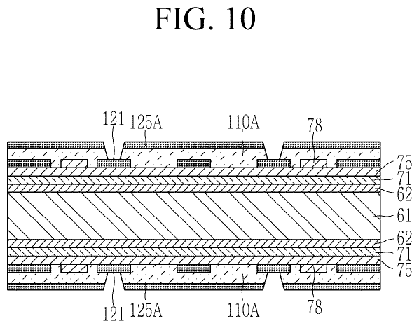

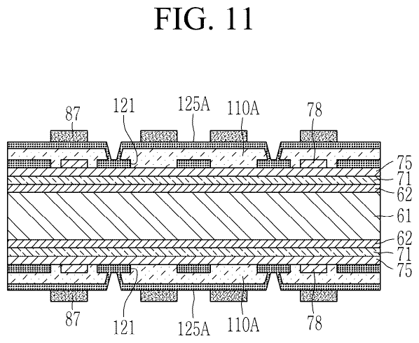

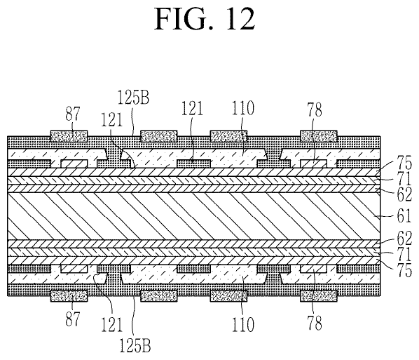

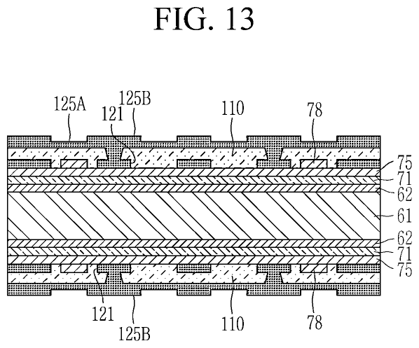

Referring to FIGS. 10 to 13, the second connection pad 125 may be formed on the insulating layer 110A through a circuit formation process. The second connection pad 125 may be formed using a method similar to a method for forming the first connection pad 121, and the second connection pad 125 may include the same type of material as that of the first connection pad 121. In this case, in order to form the via 123 that connects the first connection pad 121 and the second connection pad 125, the insulating layer 110A is partially etched to expose a portion of the first connection pad 121 (see FIG. 10), and a plating process may be performed on the exposed portion of the first connection pad 121. In addition, a third plating resist pattern 87 removed through exposure and development may be formed only at a portion where the second connection pad 125 will be formed on the second seed layer 125A (see FIG. 11). A second connection pad pattern 125B may be formed by plating the second metal having conductivity on a portion of the second seed layer 125A exposed through an opening of the third plating resist pattern 87 patterned (see FIG. 12). After the second connection pad 125 is formed, the third plating resist pattern 87 is removed (see FIG. 13). Accordingly, embedded pattern board portions may be completed on both sides of the carrier substrate 60.

According to the illustrated embodiment, each of the embedded pattern board portions is shown to include one insulating layer 110 and the first connection pad 121 and the second connection pad 125 that is two metal layers, but the present disclosure is not limited thereto. Further, a larger number of build-up insulating layers and a larger number of build-up circuit wiring pattern layers may be included, and this also falls within the scope of the present disclosure.

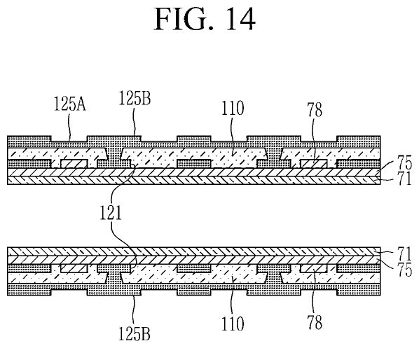

Referring to FIG. 14, an embedded pattern board is prepared by separating the first seed layer 71 from the carrier substrate 60. A pair of embedded pattern boards may be obtained by separating first seed layers 71 formed on both surfaces of the carrier substrate 60 from the copper foil layer 62, and a process may be individually applied to each of the pair of embedded pattern boards.

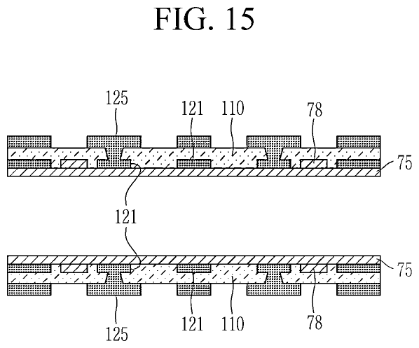

Referring to FIG. 15, the first seed layer 71 and the second seed layer 125A are removed by alkali etching the embedded pattern board obtained in FIG. 14. If the first seed layer 71 and the second seed layer 125A are removed, the conductive layer 75 and the protruding pattern layer 78 are disposed on one surface of the insulating layer 110 where the first connection pad 121 is embedded, and the second connection pad 125 protrudes from the other surface of the insulating layer 110. During the alkali etching, the first seed layer 71 and the second seed layer 125A made of the second metal are etched and removed, but the conductive layer 75 and the protruding pattern layer 78 made of the first metal remain without being etched.

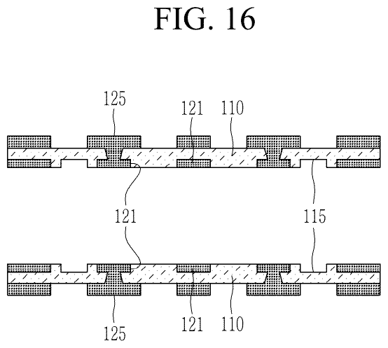

Referring to FIG. 16, the conductive layer 75 and the protruding pattern layer 78 are removed by etching the embedded pattern board obtained in FIG. 15. For this purpose, an etching process may be performed using an etching solution that does not etch the second metal included in the connection pads 121 and 125 while etching the first metal included in the conductive layer 75 and the protruding pattern layer 78. For example, by using a tin (Sn) stripper, tin (Sn) may be removed, and copper (Cu) may be etched so that it is not removed.

If the conductive layer 75 and the protruding pattern layer 78 are removed from the embedded pattern board, the first connection pad 121 is exposed from one surface of the insulating layer 110, and the trench portion 115 is formed in the insulating layer 110. Because the protruding pattern layer 78 is removed, the trench portion 115 is formed by being concavely recessed from one surface of the insulating layer 110 where the first connection pad 121 is exposed. Because the first connection pad 121 made of the first metal is not etched by an etching solution that etches the second metal, an exposed surface of the first connection pad 121 may be disposed on the same surface as the one surface of the insulating layer 110.

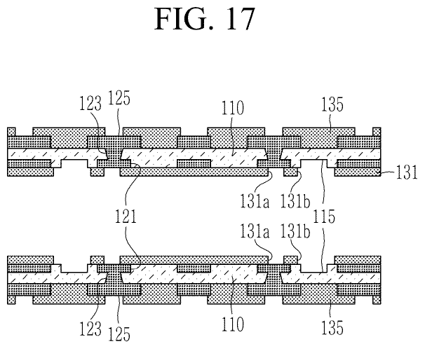

Referring to FIG. 17, the first and second protective layers 131 and 135 are formed to cover the insulating layer 110 and the connection pads 121 and 125 on both surfaces of the embedded pattern board obtained in FIG. 16. The first and second protective layers 131 and 135 may include a solder resist layer. The first protective layer 131 may be patterned to include the first opening 131a that is opened to expose the first connection pad 121 and the second opening 131b that is opened to expose the trench portion 115 on one surface of the insulating layer 110 where the first connection pad 121 is exposed. In terms of a width along the first direction parallel to one surface of the insulating layer 110, a width of the second opening 131b may be formed to be larger than a width of the trench portion 115. Additionally, in terms of the width along the first direction, a width of the first opening 131a may be formed to be smaller than a width of the first connection pad 121. The second protective layer 135 may be opened to expose at least a portion of the second connection pad 125 on the other surface of the insulating layer 110 where the second connection pad 125 is disposed.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A circuit board comprising:
an insulating layer that has a first surface and a second surface facing each other and includes a trench portion concavely recessed from the first surface of the insulating layer;
a first connection pad that is embedded within the insulating layer and is exposed from the first surface of the insulating layer; and
a first protective layer that covers the insulating layer and is opened to expose the first connection pad and the trench portion from the first surface of the insulating layer.

2. The circuit board of claim 1, wherein the first protective layer includes a first opening exposing the first connection pad and a second opening exposing the trench portion.

3. The circuit board of claim 2, wherein in terms of a width along a first direction parallel to the first surface of the insulating layer, a width of the second opening is greater than a width of the trench section.

4. The circuit board of claim 2, wherein in terms of a width along a first direction parallel to the first surface of the insulating layer, a width of the first opening is less than a width of the first connection pad.

5. The circuit board of claim 1, wherein a bottom surface of the trench portion is disposed to be further retreated than an exposed surface of the first connection pad.

6. The circuit board of claim 5, wherein the bottom surface of the trench portion is disposed to be further retreated than a bottom surface of the first connection pad.

7. The circuit board of claim 5, wherein a recessed depth of the trench portion is greater than a thickness of the first connection pad along a second direction perpendicular to the first surface of the insulating layer.

8. The circuit board of claim 5, wherein a recessed depth of the trench portion is less than a thickness of the insulating layer along a second direction perpendicular to the first surface of the insulating layer.

9. The circuit board of claim 1, wherein the trench portion is disposed adjacent to the first connection pad.

10. The circuit board of claim 1, further comprising a plurality of first connection pads including the first connection pad, wherein the trench portion is disposed between first connection pads that are adjacent to each other among the plurality of first connection pads.

11. The circuit board of claim 1, wherein an exposed surface of the first connection pad is disposed on the same surface as the first surface of the insulating layer.

12. The circuit board of claim 1, further comprising a second connection pad disposed to protrude from the second surface of the insulating layer.

13. The circuit board of claim 12, further comprising a second protective layer that at least partially covers the insulating layer and the second connection pad on the second surface of the insulating layer.

14. The circuit board of claim 1, wherein the insulating layer includes a prepreg (PPG).

15. The circuit board of claim 1, wherein the protective layer includes a solder resist (SR).

16. A method of fabricating a circuit board, comprising:
forming a conductive layer including a first metal on a seed layer including a second metal;
patterning a first plating resist covering the conductive layer and plating the first metal to form a protruding pattern layer on the conductive layer;
patterning a second plating resist covering the conductive layer and the protruding pattern layer, and plating the second metal to form a connection pad on the conductive layer;
forming an insulating layer to cover the protruding pattern layer and the connection pad; and
removing the protruding pattern layer by etching the protruding pattern layer and forming a trench portion concavely recessed on a surface of the insulating layer.

17. The method of claim 16, further comprising forming a protective layer opened to expose the connection pad and the trench portion on the surface of the insulating layer.

18. The method of claim 16, wherein the second metal includes copper (Cu) and the first metal includes tin (Sn).

19. The method of claim 16, wherein the trench portion is formed at a portion corresponding to the protruding pattern layer.
